(19) United States
(12) Patent Application Publication
(10) Pub. No.: US 2026/0223348 A1
(43) Pub. Date: Jul. 30, 2026

(54) MEMORY DEVICE WITH ISOLATION STRUCTURES AND METHOD FOR FORMING SAME

(71) Applicant: Taiwan Semiconductor Manufacturing Company, Ltd., Hsin-Chu (TW)

(72) Inventors: Feng-Ming Chang, Hsinchu County (TW); Jui-Wen Chang, Hsinchu (TW)

(21) Appl. No.: 19/262,867

(22) Filed: Jul. 8, 2025

Related U.S. Application Data
(60) Provisional application No. 63/749,565, filed on Jan. 25, 2025.

(51) Int. Cl. H10B 10/00; H10D 30/00; H10D 30/01; H10D 30/43; H10D 62/10; H10D 62/13

(52) U.S. Cl. CPC H10B 10/12; H10B 10/18; H10D 30/014; H10D 30/0191; H10D 30/43; H10D 30/502; H10D 62/121; H10D 62/151

(57) ABSTRACT

A semiconductor structure includes active regions distributed along a first direction and each extending lengthwise along a second direction perpendicular to the first direction, gate lines distributed along the second direction and each extending lengthwise along the first direction, a first active region break intersecting a first one of the active regions, a second active region break intersecting a second one of the active regions, and an isolation structure abutting the first and second active region breaks and extending lengthwise along the first direction. The isolation structure is disposed between the first and second ones of the active regions along the first direction.

### PRIORITY DATA

This application claims priority to U.S. Provisional Patent Application No. 63/749,565 filed on Jan. 25, 2025, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Memories are commonly used in ICs. For example, static random-access memory (SRAM) is a type of volatile memory widely used in electronic applications where high speed, low power consumption, and simplicity of operation are generally needed. Embedded SRAM is particularly popular in high-speed communications, image processing, and system-on-chip (SOC) applications. SRAM has the advantage of being able to hold data without requiring a refresh. An SRAM macro typically includes memory blocks and associated peripheral circuits. The memory blocks contain memory bit cells arranged in rows and columns as an array. The peripheral circuits include input/output (I/O) circuitry and other control circuits. Dummy cells may be inserted between the array of memory bit cells and the peripheral circuits to provide a transitional buffer region. However, isolation structures separating the dummy cells from functional memory bit cells located at the edges of the array (also referred to as edge cells) may adversely affect the operation of those edge cells, potentially leading to a higher failure bit count (FBC) for edge cells compared to other memory bit cells located centrally within the array (also referred to as center cells). The isolation structures thus have an impact on the yield and design performance of the IC. Accordingly, there is a need for improved isolation structures in memory devices to address these challenges.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a block diagram of a semiconductor device that includes a memory macro, in accordance with some embodiments of the present disclosure.

FIG. 2 illustrates a circuit schematic for a static random-access memory (SRAM) cell, in accordance with some embodiments of the present disclosure.

FIG. 3 illustrates a layout of the SRAM cell as in FIG. 2, in accordance with some embodiments of the present disclosure.

FIG. 4 illustrates a layout of a portion of a memory array formed by the SRAM cells as in FIG. 3, in accordance with some embodiments of the present disclosure.

FIGS. 5, 6, 7, and 8 illustrate layouts of a portion of the memory macro as in FIG. 1, in accordance with some embodiments of the present disclosure.

FIGS. 9A and 9B illustrate cross-sectional views along cut lines A-A and B-B of the layouts as in FIGS. 5 and 7, respectively, in accordance with some embodiments of the present disclosure.

FIGS. 10A, 10B, 11A, 11B, 12A, 12B, 13A, 13B, 14A, and 14B illustrate fragmentary cross-sectional views of a semiconductor device during a fabrication process, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/-10% of the number described, unless otherwise specified. For example, the term “about 5 nm” encompasses the dimension range from 4.5 nm to 5.5 nm.

The present disclosure is generally related to memory blocks including a memory array containing memory bit cells and a dummy cell region containing dummy cells serving a transitional zone from the memory array to associated peripheral circuits, and more particularly to isolation structures further separating the dummy cells from the memory bit cells located at the edges of the memory array. The memory bit cells are configured to store memory bits and are also simply referred to as bit cells. The memory array includes the memory cells arranged in rows and columns and is also simply referred to as an array. The bit cells located at the edges of the array may also be referred to as edge cells, and other bit cells away from the edges of the array may also be referred to as center cells. The present disclosure mainly uses static random-access memory (SRAM) as an example to illustrate various embodiments of the application. It is understood, however, that the application should not be limited to a particular type of memory devices, except as specifically claimed.

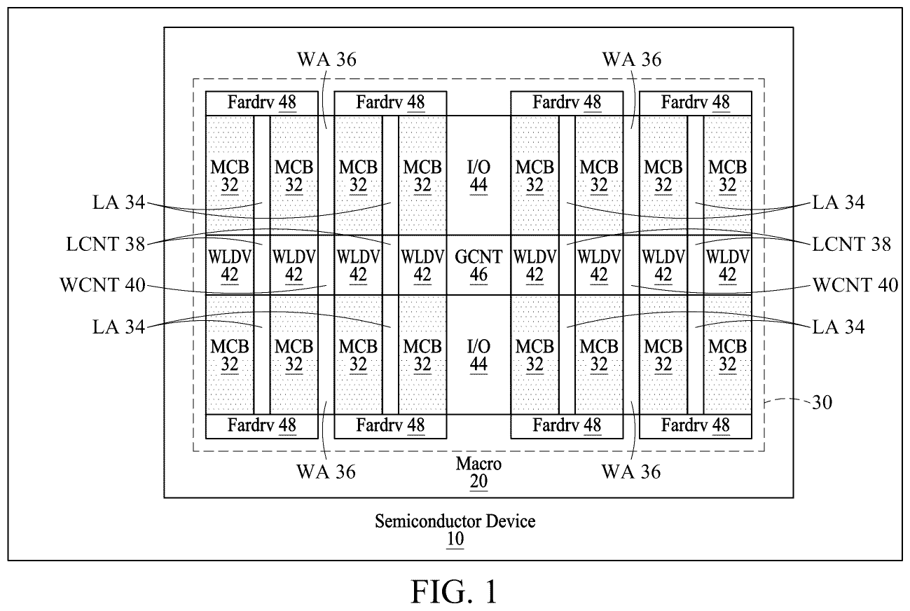

Reference now is made to FIG. 1. FIG. 1 is a simplified block diagram of a semiconductor device (or IC) 10, in accordance with some embodiments of the present disclosure. The semiconductor device 10 can be, e.g., a microprocessor, an application specific integrated circuit (ASIC), a field programmable gate array (FPGA), a digital signal processor (DSP), or a portion thereof, that includes various passive and active microelectronic devices such as resistors, capacitors, inductors, diodes, p-type field effect transistors (PFETs), n-type field effect transistors (NFETs), fin field-effect transistors (FinFET), gate-all-around (GAA) transistors, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. The exact functionality of the semiconductor device 10 is not a limitation to the provided subject matter.

The semiconductor device 10 includes a circuit macro 20. The circuit macro 20 is also simply referred to as macro 20. In some embodiments, the macro 20 is an SRAM macro that includes volatile memories in the form of SRAM. However, the present disclosure contemplates embodiments, where macro 20 is another type of memory, such as a dynamic random-access memory (DRAM), a non-volatile random access memory (NVRAM), a flash memory, or other suitable memory.

FIG. 1 also illustrates a region 30 as a portion of the macro 20 in accordance with some embodiments of the present disclosure. The block diagram of the region 30 presents a top-view representation of a repeating segment in the macro 20 that includes memory cell blocks (MCB) 32 and surrounding peripheral circuits. The illustrated block diagram has been simplified for clarity to highlight the spatial arrangement and functional partitioning of the building blocks within the macro 20. Additional features can be added in the macro 20, and some of the features described below can be replaced, modified, or eliminated in other embodiments of the macro 20.

The memory cell blocks 32 form the core of the macro 20. Each memory cell block 32 contains a memory array of SRAM bit cells arranged in a grid of rows and columns. In one embodiment, each memory cell block 32 includes a memory array of 16×48 SRAM bit cells, although other sizes are possible depending on the desired memory density and layout granularity. The memory cell blocks 32 are repeated horizontally and vertically across the layout of the macro 20. The bit cells within each memory cell block 32 are accessed through associated word lines (WL) and bit lines (BL), which are controlled and driven by peripheral circuits located adjacent to the memory cell blocks 32.

Surrounding the memory cell blocks 32 are various logic and support circuits configured to enable the read and write operations of the memory array. In the illustrated embodiment, to the immediate left and right of a memory cell block 32 is either a local I/O area (LA) 34 or a write assist area (WA) 36. The local I/O areas 34 and the write assist areas 36 serve as the immediate interface between the bit cells and the rest of the memory system. The local I/O areas 34 may include sense amplifiers for read operations and write drivers for write operations, and may also include pass-gate logic, data multiplexers, or pre-charge devices. The write assist areas 36 help improving write margin by applying write assist techniques, including but not limited to applying a negative voltage to the bit lines during the write operation to enhance the write margin, reducing the word line voltage during the write operation to improve write-ability, and/or using a sense amplifier to detect the state of the cells and enhance the write operation.

Located between two vertically adjacent local I/O areas 34 is a local control (LCNT) circuit 38. Located between two vertically adjacent write assist areas 36 is a write control (WCNT) circuit 40. Located between two vertically adjacent memory cell blocks 32 is a word line driver (WLDV) circuit 42. The local control circuits 38 generate local control signals used to activate word line drivers, enable local I/O logic, and manage timing coordination within subarrays in the memory arrays. The write control circuits 40 generate write-related control signals and coordinate with write assist logic to modulate voltages and signal timing during write operations. The word line driver circuits 42 include word line drivers to receive control signals from the local control circuits 38 and drive the corresponding word lines within each memory cell block 32 to perform row-level access during read or write operations. The word line drivers are generally designed to handle high capacitive loads and provide sharp signal transitions to ensure proper word line activation.

At the horizontal center of the region 30 is a column of I/O blocks 44 and global control (GCNT) blocks 46. The I/O blocks 44 serve as the global interface for data entering or leaving the memory macro and may include data bus logic, global read/write multiplexers, and alignment buffers. Positioned between two vertically adjacent I/O blocks 44 is the global control block 46. The global control block 46 is responsible for generating top-level timing, address decoding, and command signals that coordinate the operation of the entire SRAM macro. These global signals are distributed to the local control circuits 38 and write control circuits 40 throughout the array.

At the far ends of the layout are the far-end driver logic (Fardrv) blocks 48. The far-end driver logic blocks 48 function as terminations or repeaters for global signal distribution lines and can be used to buffer signals traveling across long distances in the macro 20. The far-end driver logic blocks 48 help preserve signal integrity and timing precision at the macro level.

The local I/O areas 34, write assist areas 36, local control circuits 38, write control circuits 40, word line driver circuits 42, I/O blocks 44, and global control blocks 46 are collectively referred to as peripheral circuits or logic circuits. Taken together, the block diagram in the region 30 represents a hierarchical and modular SRAM layout that enables efficient scaling and integration in a larger memory macro. Each memory cell block 32 is flanked by a structured set of peripheral circuits that provide localized functionality (I/O, word line drive, control), while global control and I/O circuits are centrally located to minimize signal skew and timing variation. This arrangement provides balanced access paths for read/write operations and supports efficient signal distribution throughout the array. The physical proximity and tight integration of memory cell block 32 with their neighboring logic blocks help reduce access latency and enhance overall performance. Additionally, the symmetry and regularity of the layout contribute to better manufacturability and predictable electrical behavior, making it well-suited for implementation in advanced technology nodes where area efficiency and design reliability are important.

Transistors in the memory cell blocks 32 and the logic circuits may be implemented with various p-type transistors (PFETs) and n-type transistors (NFETs) such as planar transistors or non-planar transistors including various FinFET transistors, GAA transistors, or a combination thereof. GAA transistors refer to transistors having gate electrodes surrounding transistor channels, such as vertically-stacked gate-all-around horizontal nanowire or nanosheet MOSFET devices. The following disclosure will continue with one or more GAA examples to illustrate various embodiments of the present disclosure. It is understood, however, that the application should not be limited to a particular type of transistor, except as specifically claimed. For example, aspects of the present disclosure may also apply to implementation based on FinFETs or planar FETs.

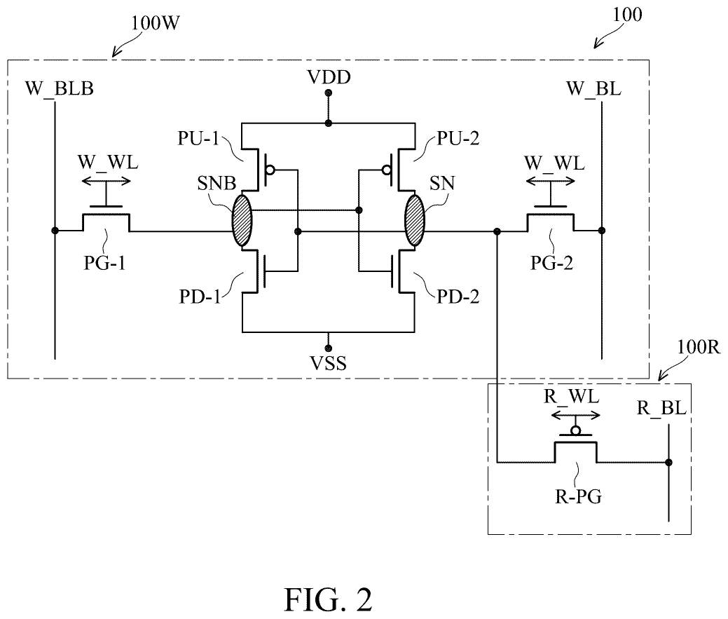

FIG. 2 is a circuit diagram of an exemplary SRAM cell 100, which can be implemented as a bit cell in each memory cell block 32 in FIG. 1, according to various aspects of the present disclosure. In the illustrated embodiment, the SRAM cell 100 is a two-port seven-transistor (7T) SRAM cell. The two-port SRAM cell 100 includes a write-port 100W and a read-port 100R. The write-port 100W includes pull-up transistors PU-1, PU-2, pull-down transistors PD-1, PD-2, and pass-gate transistors PG-1, PG-2. In the illustrated embodiment, transistors PU-1 and PU-2 are p-type transistors, and transistors PG-1, PG-2, PD-1, and PD-2 are n-type transistors. In various embodiments, the SRAM cell 100 may be other types of memory cells, such as a single-port memory cell or a memory cell having six transistors (6T) or more than seven transistors. FIG. 2 has been simplified for the sake of clarity to better understand the inventive concepts of the present disclosure. Additional features can be added in the SRAM cell 100, and some of the features described below can be replaced, modified, or eliminated in other embodiments of the SRAM cell 100.

The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with the transistors PU-2 and PD-2 to form a data latch. The gates of the transistors PU-1 and PD-1 are coupled together and to the common drains of the transistors PU-2 and PD-2 to form a storage node SN, and the gates of the transistors PU-2 and PD-2 are coupled together and to the common drains of the transistors PU-1 and PD-1 to form a complementary storage node SNB. Sources of the pull-up transistors PU-1 and PU-2 are coupled to a power voltage Vdd (also referred to as Vcc), and the sources of the pull-down transistors PD-1 and PD-2 are coupled to a voltage Vss, which may be an electrical ground in some embodiments.

The storage node SN of the data latch is coupled to a bit line W_BL of the write-port 100W through the pass-gate transistor PG-2, and the complementary storage node SNB is coupled to a complementary bit line W_BLB of the write-port 100W through the pass-gate transistor PG-1. The storage node SN and the complementary storage node SNB are complementary nodes that are often at opposite logic levels (logic high or logic low). Gates of the pass-gate transistors PG-1 and PG-2 are coupled to a word line W_WL of the write-port 100W.

The read-port 100R of the SRAM cell 100 includes a read-port pass-gate transistor (R-PG) coupled between the bit line R_BL and the storage node SN (or to the gates of the transistors PU-1 and PD-1). The gate of the read-port pass-gate transistor R-PG is coupled to a word line R_WL of the read-port 100R. In the illustrated embodiment, the transistor R-PG is a p-type transistor. That is, in the two-port SRAM cell 100, the pass-gate transistors in a write-port are n-type transistors, and the pass-gate transistor in a read-port is a p-type transistor.

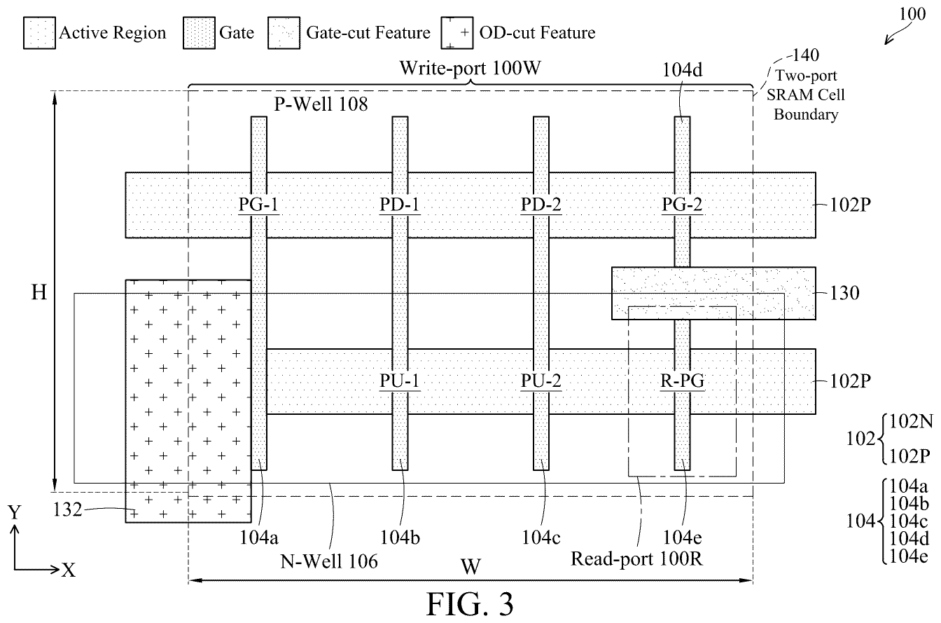

FIG. 3 illustrates a simplified diagrammatic layout of the device layer of the two-port SRAM cell 100, which includes the write-port 100W and the read-port 100R. The write-port 100W includes the transistors PG-1, PG-2, PU-1, PU-2, PD-1, and PD-2. The read-port 100R includes the transistor R-PG. For reasons of visual clarity and simplicity, the illustrated layout includes active regions and gate structures of those transistors in the SRAM cell 100, together with some isolation structures (also referred to as isolation features) dividing the gate structures or the active regions, while numerous other features in or above the device layer such as contacts, vias, and metal lines are not included in the illustrated layout. Because an active region is sometimes disposed in and defined by a silicon-oxide containing isolation feature (such as a shallow trench isolation, or STI), an active region may be referred to as oxide-definition regions or “ODs.” An isolation feature dividing an active region into segments may also be referred to as an OD-cut feature or an OD break, while an isolation feature diving a gate structure into segments may be referred to as a gate-cut feature.

The two-port SRAM cell 100 includes two active regions 102N and 102P, collectively denoted as active region 102. The active regions 102 each extend lengthwise in the X-direction in FIG. 3. In the illustrated embodiment, the active regions 102 may each include (or may be implemented as) vertically-stacked nanostructures in GAA transistors or may include fin-shape structures in FinFETs. The active region 102N is a part of the write-port 100W, and the active region 102P has a side portion as a part of the read-port 100R and rest portion as a part of the write-port 100W. In other words, the active region 102P is shared by the read-port 100R and the write-port 100W. In the illustrated embodiment, the active region 102P provides channel regions and source/drain regions to the transistors PU-1, PU-2, R-PG, which are PMOS devices. As such, the active region 102P is formed over an n-well 106. Meanwhile, the active region 102N provides channel regions and source/drain regions to the transistors PG-1, PD-1, PD-2, PG-2, which are NMOS devices. As such, the active region 102N is formed over a p-well 108 (or a p-type substrate).

The two-port SRAM cell 100 further includes gate structures 104a, 104b, 104c, 104d, 104e each extending lengthwise in the Y-direction, collectively denoted as gate structures 104. The gate structures 104a, 104b, 104c, and 104d are parts of the write-port 100W. The gate structure 104e is a part of the read-port 100R. The gate structures 104a, 104b, 104c each extend through the two active regions 102. As such, the gate structure 104b is shared by the transistors PD-1 and PU-1, and the gate structure 104c is shared by the transistors PD-2 and PU-2, while the gate structure 104a is shared by the transistor PG-1 and a non-functional transistor (due to the OD-cut feature 132).

A boundary 140 of the two-port SRAM cell 100 is illustrated in FIG. 3 using broken lines. Note that some of the active regions and gate structures may extend beyond the illustrated boundary 140, since these active regions and gate structures may also form components of other adjacently located SRAM cells as well. The boundary 140 is longer in the X-direction than in the Y-direction. In other words, the boundary 140 may be rectangular. The first dimension of the boundary 140 along the X-direction is denoted as a cell width W, and the second dimension of the boundary 140 along the Y-direction is denoted as a cell height H. Where the two-port SRAM cell 100 is repeated in a memory array, the cell width W may represent and be referred to as a memory cell pitch in the memory array along the X-direction, and the cell height H may represent and be referred to as a memory cell pitch in the memory array along the Y-direction.

Still referring to FIG. 3, the two-port SRAM cell 100 further includes dielectric features as isolation structures in the SRAM cell, including a gate-cut feature 130 and an OD-cut feature 132. The gate-cut feature 130 is disposed between the active regions 102N and 102P and abuts the gate structure 104d and the gate structure 104e. In the illustrated embodiment, the gate-cut feature 130 is disposed above an interface between the n-well 106 and the p-well 108. The gate-cut feature 130 divides an otherwise continuous gate structure 104 into two isolated segments corresponding to the gate structure 104d and the gate structure 104e. The gate-cut feature 130 is formed by filling a corresponding cut-metal-gate (CMG) trench in the position of the gate-cut feature 130 with dielectric material(s). The gate-cut feature 130 is also referred to as a CMG feature. A CMG process refers to a fabrication process where after a metal gate (e.g., a high-k metal gate or HKMG) replaces a dummy gate structure (e.g., a polysilicon gate), the metal gate is cut (e.g., by an etching process) to separate the metal gate into two or more gate segments. Each gate segment functions as a metal gate for an individual transistor. An isolation material is subsequently filled into trenches between adjacent portions of the metal gate. These trenches are referred to as cut-metal-gate trenches, or CMG trenches, in the present disclosure. The dielectric material filling a CMG trench for isolation is referred to as a CMG feature. To ensure a metal gate would be completely cut, a CMG feature often further extends into adjacent areas, such as dielectric layers filling space between the metal gates. A CMG feature often have an elongated shape in a top view. In the illustrated embodiment, the gate-cut feature 130 extends lengthwise along the X-direction. Although not depicted in FIG. 3, the gate structures 104a, 104b, 104c are also separated from respective counterparts in adjacent SRAM cells 100 by other gate-cut features 130. In other words, the corresponding gate structures aligned in the Y-direction from multiple SRAM cells in the same column can be considered as segments of an otherwise continuous gate line. Hence, the gate structures 104 may also be referred to as gate lines 104 representing the collection of the segments.

The OD-cut feature 132 cuts the active region 102P and blocks one end of the active region 102P from extending beyond a boundary 140 of the two-port SRAM cell 100. The OD-cut feature 132 may also be referred to as an active region break 132. The OD-cut feature 132 abuts a sidewall of the gate structure 104a along the Y-direction. Due to the OD-cut feature 132, the intersection where the gate structure 104a across the active region 102P does not form a functional transistor but a non-functional transistor. The formation of the OD-cut feature 132 may include etching a portion of the active region 102P in a lithography process to form a recess at the position of the OD-cut feature 132 and filling the recess with dielectric material(s). Since the active region 102 may have a fin-like shape, the OD-cut process may also be referred to as a fin-cut process, and the OD-cut feature 132 may also be referred to as a fin-cut feature 132. An OD-cut feature often has an elongated shape in a top view. In the illustrated embodiment, the OD-cut feature 132 extends lengthwise along the Y-direction.

The cell size of the two-port SRAM cell 100 is W×H, in which the cell width W is about 4 times a poly pitch (e.g., a center-to-center distance between two adjacent gate structures along the X-direction, also referred to as a gate pitch) and the cell heigh H is about 2 times an OD pitch (e.g., a center-to-center distance between two adjacent active regions along the Y-direction, also referred to as an active region pitch). Denoting an area of one poly pitch times one OD pitch as a unit area, each unit area includes an intersection of a gate structure and an active region, and the two-port SRAM cell 100 utilizes a cell size of about 8 times a unit area in accommodating the seven transistors, namely the transistors PG-1, PG-2, PU-1, PU-2, PD-1, PD-2, and R-PG. The area utilization at the device layer of the SRAM cell 100 is considered efficient as there is only one unit area not utilized for forming a functional transistor but hosting a non-functional transistor due to the OD-cut feature 132.

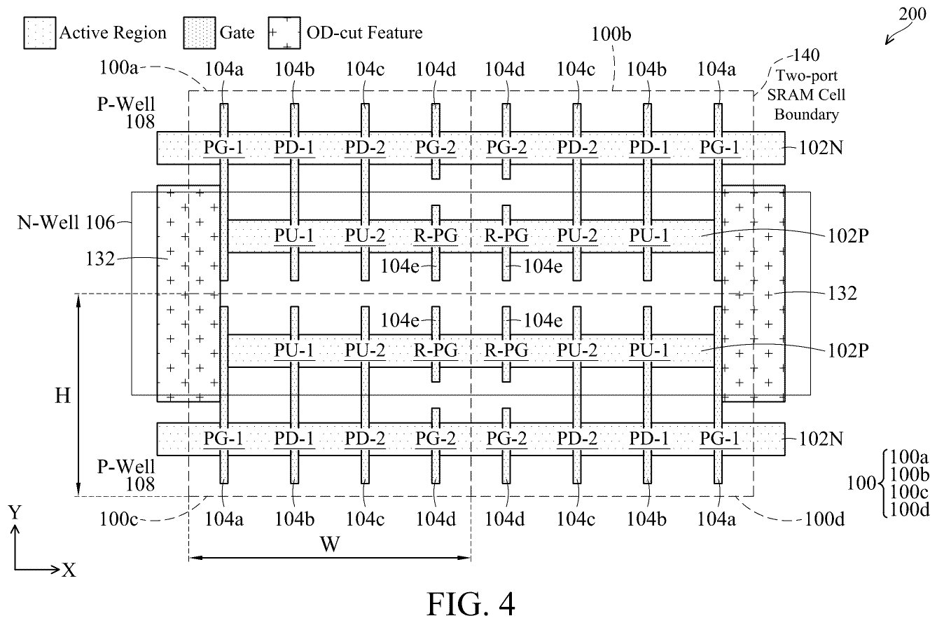

FIG. 4 illustrates a simplified diagrammatic layout of a portion of an SRAM array 200 located in the memory cell block 32 in FIG. 1, according to various aspects of the present disclosure. For reasons of visual clarity and simplicity, the illustrated layout includes active regions and gate structures of those transistors in the array, together with well regions and OD-cut features, while numerous other features such as gate-cut features, contacts, vias, and metal lines are not included in the illustrated layout.

The SRAM cells 100 are arranged in the X-direction and the Y-direction in forming the array 200. The illustrated portion of the array 200 as shown in FIG. 4 includes four SRAM cells 100 (denoted as 100a, 100b, 100c, and 100d) in forming a 2×2 subarray. Each SRAM cell 100 may use the layout of as depicted in FIG. 3. In some embodiments, two adjacent SRAM cells in the X-direction are line symmetric with respect to a common boundary therebetween, and two adjacent SRAM cells in the Y-direction are line symmetric with respect to a common boundary therebetween. That is, the SRAM cell 100b is a duplicate cell for the SRAM cell 100a but flipped over the Y-axis; the SRAM cell 100c is a duplicate cell for the SRAM cell 100a but flipped over the X-axis; and the SRAM cell 100d is a duplicate cell for the SRAM cell 100b but flipped over the X-axis.

The SRAM array 200 includes well regions 106 and 108 alternately arranged along the Y-axis. In other words, every p-well region 108 is next to an n-well region 106 which is next to another p-well region 108, and this pattern repeats. The active regions 102 each extend through the SRAM cells 100 in the same row unless divided by the OD-cut features 132. Each OD-cut feature 132 is shared by immediate neighboring SRAM cells 100. An edge-to-edge distance between two adjacent OD-cut features along the X-direction is about 7 times a poly pitch. In the illustrated embodiment, the gate structures in each SRAM cell 100 do not extend beyond the respective cell boundary. In an alternative layout, some gate structures may be shared by neighboring SRAM cells, such that these gate structures extend lengthwise across the boundary between neighboring SRAM cells. For example, the two transistors R-PG in the two adjacent SRAM cells 100 in the same column (arranged along the Y-direction) may share the same gate structure 104e, such that the shared gate structure 104e may extend lengthwise across the boundary between the two adjacent SRAM cells 100. In another example, the two transistors PG-1 in the two adjacent SRAM cells 100 in the same column (arranged along the Y-direction) may share the same gate structure 104a, such that the shared gate structure 104a may extend lengthwise across the boundary between the two adjacent SRAM cells 100. In yet another example, the two transistors PG-2 in the two adjacent SRAM cells 100 in the same column (arranged along the Y-direction) may share the same gate structure 104d, such that the shared gate structure 104d may extend lengthwise across the boundary between the two adjacent SRAM cells 100.

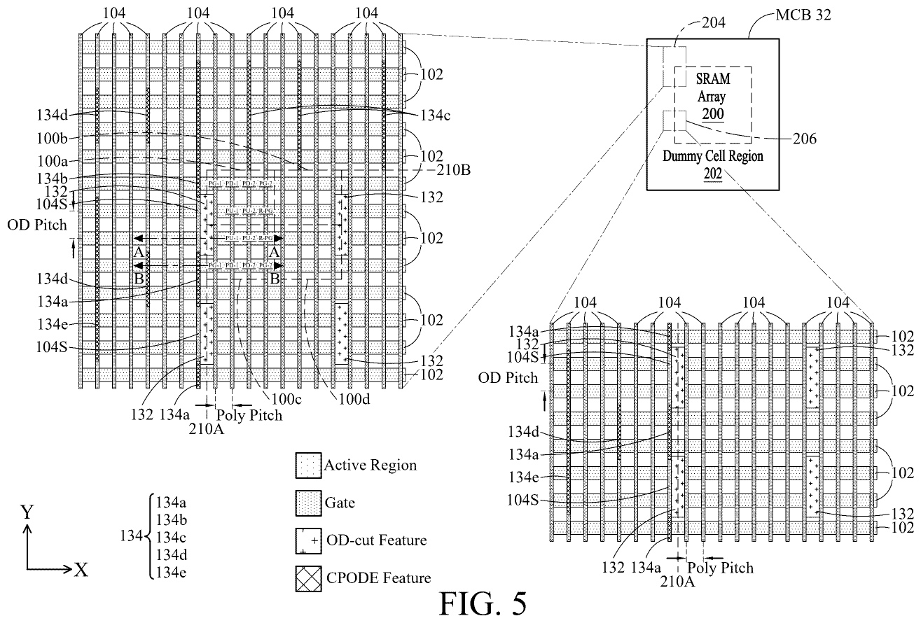

Reference is now made to FIG. 5. FIG. 5 illustrates one of the memory cell blocks 32 in FIG. 1, according to various aspects of the present disclosure. The memory cell block 32 includes a first cell region 200 that includes an SRAM array (also referred to as the SRAM array 200) and a second cell region 202 that includes dummy cells (also referred to as the dummy cell region 202). Particularly, FIG. 5 illustrates simplified diagrammatic layouts of a region 204 and a region 206 located in the memory cell block 32. The region 204 includes a corner region of the SRAM array 200 and a portion of the dummy cell region 202 abutting the corner region of the SRAM array 200, while the region 206 includes an edge region of the SRAM array 200 and a portion of the dummy cell region 202 abutting the edge region of the SRAM array 200. For reasons of visual clarity and simplicity, the illustrated layout includes active regions and gate structures of those transistors in the array, together with some isolation structures including OD-cut features 132 and cut-on-poly-oxide-definition-edge (CPODE) features 134, while numerous other features such as gate-cut features, contacts, vias, and metal lines are not included in the illustrated layout.

Referring to the regions 204 and 206 collectively, the dashed lines 210A and 210B mark the edges of the SRAM array 200 along the Y-direction and the X-direction, respectively. The intersection of the dashed lines 210A and 210B marks a corner of the SRAM array 200. Four SRAM cells 100a, 100b, 100c, 100d as in FIG. 4 are also denoted in FIG. 5. Since the SRAM cells 100a, 100b, and 100c, among others, are disposed along the edges of the SRAM array 200, these SRAM cells are also referred to as the edge cells. Other SRAM cells not disposed along the edges are referred to as the center cells. Similarly, some of the OD-cut features 132 are disposed on the edge 210A of the SRAM array 200 and are shared between the SRAM array 200 and the dummy cell region 202. These OD-cut features 132 are also referred to as the edge OD-cut features. Other OD-cut features 132 fully within the SRAM array 200 are referred to as the center OD-cut features. Outside of the dashed lines 210A and 210B and beyond the corner of the SRAM array 200 is the dummy cell region 202.

As discussed above with respect to FIG. 1, surrounding the memory cell block 32 are various peripheral circuits, such as logic regions containing logic cells. The logic cells may be standard cells, such as invertor (INV), AND, OR, NAND, NOR, flip-flop, SCAN and so on. The logic cells implement various logic functions to the bit cells in the SRAM array 200. The logic functions of the logic cells include, for example, write and/or read decoding, word line selecting, bit line selecting, data driving and memory self-testing. However, direct adjacency between the SRAM array 200 in the memory cell block 32 and these peripheral circuits can introduce layout and performance challenges, such as electrical interference, mismatched signal loading, and process variation sensitivity at the boundary regions. To address these concerns, a dummy cell region 202 is introduced between the SRAM array 200 and the peripheral circuits as a transitional buffer zone. The dummy cell region 202 comprises non-functional or inactive cells that mimic the physical and electrical characteristics of active SRAM cells but do not participate in memory operations. This dummy cell region 202 acts as a buffer region that isolates the functional memory array from process or layout anomalies at the boundary, improves pattern density uniformity during lithography, and enhances matching conditions for edge cells within the active array. The inclusion of the dummy cell region 202 helps ensure more uniform electrical behavior across the SRAM array 200 and contributes to improved yield, stability, and overall reliability of the memory device.

In the illustrated layout, the active regions 102 are evenly distributed along the Y-direction with the spacing of an OD pitch and each oriented lengthwise in the X-direction. Except those active regions 102 that are divided by the OD-cut features 132, other active regions 102 extend continuously through the cells arranged in the same row, including the cells in the SRAM array 200 and the cells in the dummy cell region 202. The gate lines 104 are evenly distributed along the X-direction with the spacing of a poly pitch and etch oriented lengthwise in the Y-direction. Inside the bit cells in the SRAM array 200, the gate lines 104 are divided into segments, as discussed above with respect to FIGS. 3 and 4, by the gate-cut features, such as the gate-cut feature 130 in FIG. 3. In the dummy cell region 202, the gate lines 104 extend continuously unless divided by the CPODE features 134.

The CPODE features 134 are isolation structures formed in a cut-on-poly-oxide-definition-edge (CPODE) process. In a CPODE process, a polysilicon gate is replaced by a dielectric feature. The edge defined between the poly (e.g., a dummy gate structure) and oxide (e.g., STI features) is an active edge abuts active regions. Before the CPODE process, the active edge may include a dummy GAA structure having a dummy gate structure (e.g., a polysilicon gate) and a plurality of vertically stacked nanostructures as channel layers. In addition, inner spacers may be disposed between adjacent nanostructures at lateral ends of the nanostructures. In various examples, source/drain epitaxial features are disposed on either side of the dummy GAA structure, such that the adjacent source/drain epitaxial features are in contact with the inner spacers and nanostructures of the dummy GAA structure. The subsequent CPODE etching process removes the dummy gate structure and the channel layers from the dummy GAA structure to form a CPODE trench. The dielectric material filling a CPODE trench for isolation is referred to as a CPODE feature. In some embodiments, after the CPODE features are formed, the remaining dummy gate structures are replaced by metal gate structures in a replacement gate (gate-last) process. State differently, in some embodiments, the CPODE feature replaces a portion or full of the otherwise continuous gate structure and is confined between the opposing gate spacers of the replaced portion of the gate structure.

Since the CPODE features 134 are formed by replacing the previously-formed polysilicon gate structures, the CPODE features 134 inherit the arrangement of the gate lines 104. That is, the CPODE features 134 may have about the same width as the gate lines 104 and also extend lengthwise along the Y-direction. As a comparison, the CMG feature truncates the otherwise continuous gate structure and extends into adjacent areas of the gate structure. Accordingly, in the illustrated layout, there are at least three types of isolation structures. The first isolation structures are the CMG features (not shown in FIG. 5, but in FIG. 3). The second isolation structures are the OD-cut features (or OD breaks) 132, which are mainly disposed inside the SRAM array 200 and have some edge ones disposed along the edge 210A of the SRAM array 200. In the illustrated embodiment, there is no OD-cut feature 132 fully within the dummy cell region 202. The third isolation structures are the CPODE features 134, which are disposed in the dummy cell region 202. Some of the CPODE features 134 (e.g., 134a, 134b) interface (in direct contact with) sidewalls of the edge OD-cut features 132. Some of the CPODE features 134 (e.g., 134c) abut the edge 210B of the SRAM array 200.

Referring still to FIG. 5, a CPODE feature 134a extends between two adjacent edge OD-cut features 132. The CPODE feature 134a partially interfaces with the sidewalls of each of the two adjacent OD-cut features 132. Since two active regions 102 extend through the space between the adjacent OD-cut features 132, the CPODE feature 134a also extends across both active regions 102. Additionally, a CPODE feature 134b interfaces with the sidewall of an OD-cut feature 132 located at the corner of the SRAM array 200. Unlike CPODE feature 134a, which interfaces with both of the adjacent OD-cut features 132, CPODE feature 134b interfaces with only one OD-cut feature 132 and extends further into the dummy cell region 202.

Together, the CPODE features 134a and 134b, along with the intervening edge OD-cut features 132, form a continuous dielectric “wall” that protects the functional bit cells in the SRAM array 200 by isolating them from the dummy cells in the dummy cell region 202. Although the dielectric wall is continuous in effect, the individual CPODE features 134a and 134b are not physically connected with adjacent ones. Instead, a segment of the gate line 104, denoted as gate segment 104S, is disposed between two adjacent CPODE features 134a (or between a CPODE feature 134a and a CPODE feature 134b). The gate segment 104S is a non-functional gate structure located in the dummy cell region 202, with its sidewall interfacing the sidewall of the adjacent OD-cut feature 132. The presence of gate segment 104S prevents the CPODE features 134a and 134b from merging into a single, continuously extending CPODE feature. Forming such a continuous CPODE feature could risk damaging nearby epitaxial features. In particular, as the CPODE feature abuts the source/drain region of a functional transistor (e.g., the PG-1 transistor), the source/drain region of that transistor may be damaged, potentially increasing the failure bit count of the edge cells. By using a plurality of CPODE features 134a to replace segmented portions of the gate line 104, the length of each CPODE feature is carefully controlled to avoid such damage.

In some embodiments, the combined length of a CPODE feature 134a and an adjacent gate segment 104S along the Y-direction is four OD pitches. In further embodiments, the length of each CPODE feature 134a ranges from about 1.5 OD pitches to about 2.5 OD pitches, while the length of the corresponding gate segment 104S ranges from about 2.5 OD pitches to about 1.5 OD pitches, such that their sum remains constant. In the illustrated example, both the CPODE feature 134a and the gate segment 104S are 2 OD pitches in length. Notably, the specified range of 1.5 to 2.5 OD pitches for the CPODE feature 134a is neither arbitrary nor trivial. If the CPODE feature 134a is shorter than approximately 1.5 OD pitches, it cannot adequately span between two adjacent OD-cut features 132 to form the continuous dielectric “wall” in separating the SRAM array 200 from the dummy cell region 202. Conversely, if the CPODE feature 134a exceeds approximately 2.5 OD pitches, the risk of damaging the epitaxial region of the PG-1 transistor during the CPODE process increases, potentially resulting in malfunctioning edge bit cells.

Unlike the CPODE features 134a, the CPODE feature 134b may have a greater length. In the illustrated example, the length of CPODE feature 134b is approximately 4.5 OD pitches and extends across five active regions 102 including one extending from the SRAM array 200 and four fully within the dummy cell region 202. This increased length is feasible because only the tip of its terminal end abuts the source/drain region of a single transistor in an edge bit cell of the SRAM array 200, while the majority of its sidewalls interface with dummy cells in the dummy cell region 202. Similarly, spaced apart from the CPODE feature 134b along the X-direction are multiple CPODE features 134c, each having a terminal end that abuts edge 210B of the SRAM array 200. In the illustrated embodiment, the opposing terminal ends of the CPODE features 134c are flush (level) with that of the CPODE feature 134b. These CPODE features 134c may also be longer than the CPODE features 134a. In the illustrated example, each CPODE feature 134c has a length of approximately 4 OD pitches and extends across four active regions 102 all located in the dummy cell region 202, which is half an OD pitch shorter than CPODE feature 134b. Furthermore, the CPODE features 134c are positioned at locations corresponding to the gate lines 104 for the PD-2 and PU-2 transistors. As a result, the spacing between adjacent CPODE features 134c is non-uniform, alternating between three and five poly pitches.

Located further from the SRAM array 200, entirely within the dummy cell region 202, are additional CPODE features 134, such as the CPODE features 134d and 134e. Because these features are positioned at a sufficient distance from the functional bit cells, their impact on SRAM operation is minimal. Accordingly, their lengths can be varied, depending primarily on the design needs for test structures within the dummy cell region 202. In the illustrated example, the CPODE feature 134d has a length of approximately 2 OD pitches and extends across two active regions 102, same with the length of the CPODE features 134a. In contrast, CPODE feature 134e has a greater length of approximately 5.5 OD pitches and extends across six active regions 102, which is one OD pitch longer than the CPODE feature 134b.

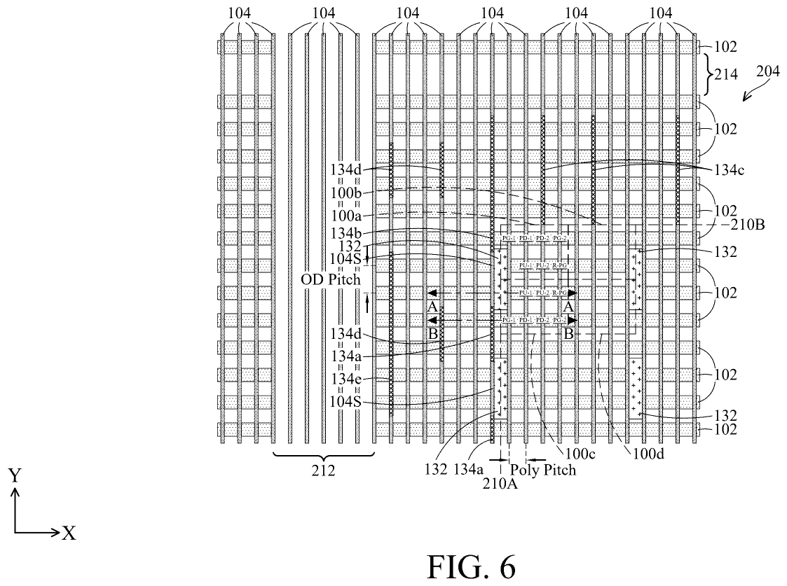

Referring to FIG. 6, in some embodiments, the dummy cell region 202 may include extra buffer zones outside of the region 204 to provide better transition from the SRAM array 200 to the peripheral circuits. In the illustrated embodiment, a buffer zone 212 extending along the Y direction and free of the active regions 102 is added to a side of the region 204, and a buffer zone 214 extending along the X direction and free of the active regions 102 is added to another side of the region 204. The gate lines 104 still extend through or across the buffer zones 212 and 214. By removing the active regions 102 from the buffer zones 212 and 214, the isolation between the SRAM array 200 and the peripheral circuits is further improved. In the illustrated embodiment, the buffer zone 212 has a width of six (6) poly pitches measured along the X direction, and the buffer zone 214 has a width of two (2) OD pitches measured along the Y direction, which is for illustrative purposes only and not intended to be limiting beyond what is specifically recited in the claims.

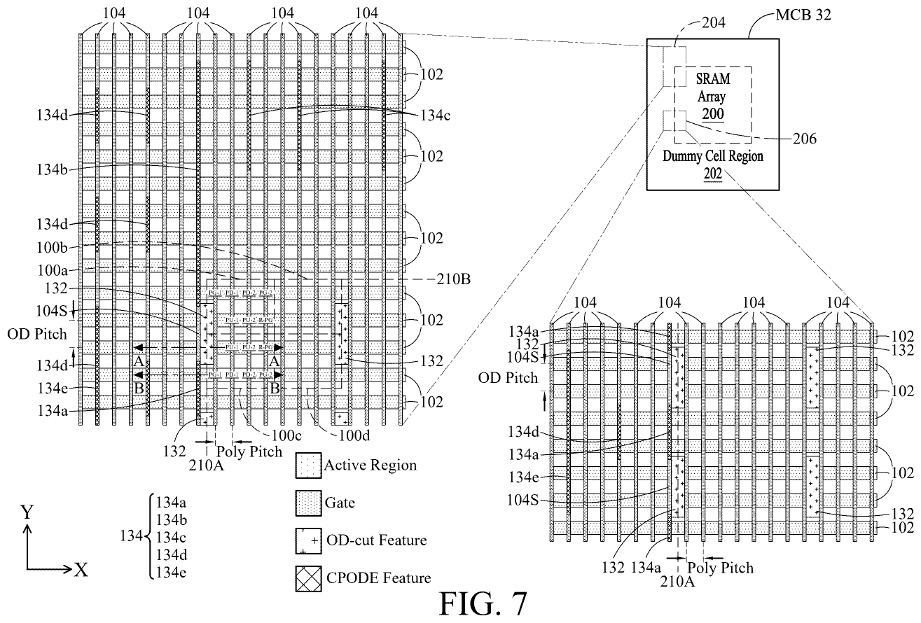

FIG. 7 illustrates an alternative embodiment to the layout in FIG. 5. Many aspects in the alternative embodiment in FIG. 7 are similar to those in FIG. 5. One difference is that the CPODE features 134c, which are abutting the edge 210B of the SRAM array 200 in FIG. 5, are further spaced apart from the edge 210B for at least one OD pitch to reduce their impact on the edge cells along the edge 210B of the SRAM array 200. In the illustrated embodiment, the CPODE features 134c are further spaced apart from the edge 210B for four OD pitches. State differently, four extra active regions 102 are inserted between the terminal ends of the CPODE features 134c and the edge 210B of the SRAM array 200. In various embodiments, the number of the extra active regions 102 may be less than four (e.g., from one to three) or more than four (but generally less than 10 due to layout area budgets) depending on performance needs. In the illustrated embodiment, the terminal ends of the CPODE features 134b and 134c that are facing away from the edge 210B are flush (level). Consequently, the length of the CPODE feature 134b is larger than in FIG. 5, which is about 8.5 OD pitches and extends across nine active regions 102, including one extending from the SRAM array 200 and eight fully within the dummy cell region 202.

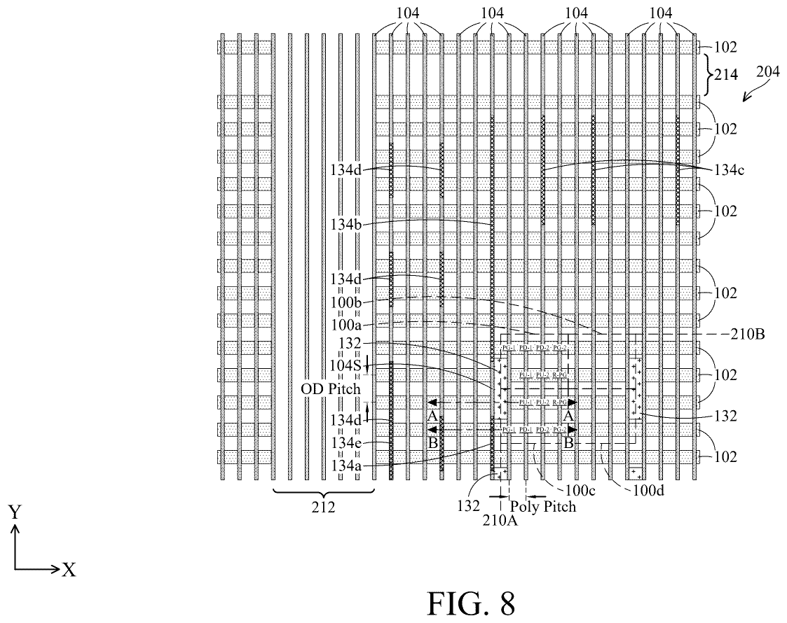

FIG. 8 illustrates that outside of the region 204 as in FIG. 7, in some embodiments, the dummy cell region 202 may include extra buffer zones to provide better transition from the SRAM array 200 to the peripheral circuits. In the illustrated embodiment, a buffer zone 212 extending along the Y direction and free of the active regions 102 is added to a side of the region 204, and a buffer zone 214 extending along the X direction and free of the active regions 102 is added to another side of the region 204. The gate lines 104 still extend through or across the buffer zones 212 and 214. By removing the active regions 102 from the buffer zones 212 and 214, the isolation between the SRAM array 200 and the peripheral circuits is further improved. In the illustrated embodiment, the buffer zone 212 has a width of six (6) poly pitches measured along the X direction, and the buffer zone 214 has a width of two (2) OD pitches measured along the Y direction, which is for illustrative purposes only and not intended to be limiting beyond what is specifically recited in the claims.

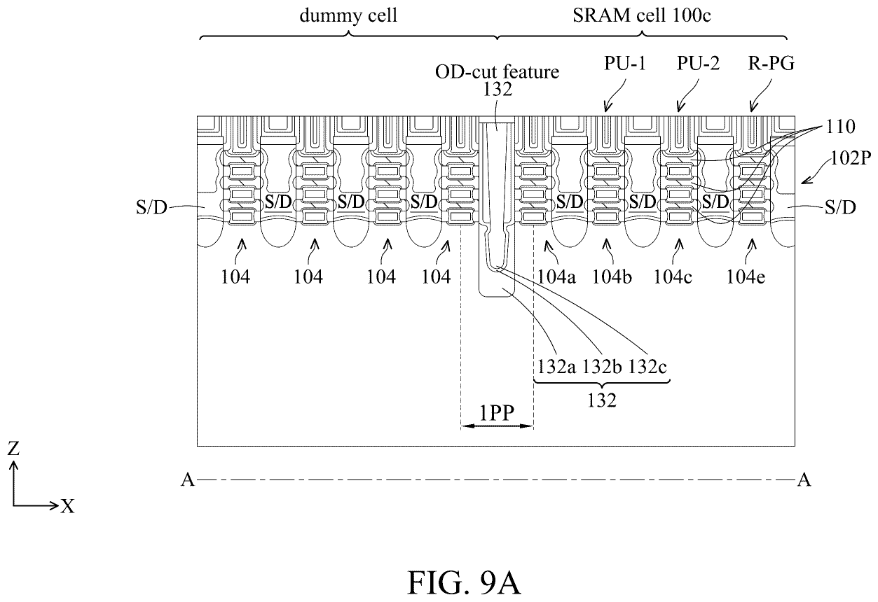

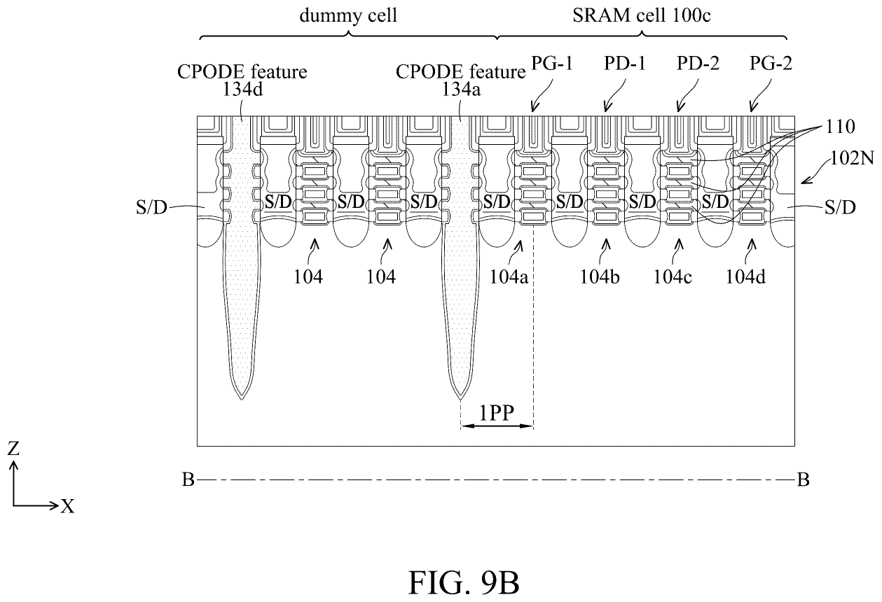

FIGS. 9A and 9B are fragmentary cross-sectional views taken along lines A-A and B-B of FIG. 5 (or FIG. 7), respectively. The A-A line intersects an active region 102, specifically a p-type active region 102P that defines the channel and source/drain (S/D) regions for transistors PU-1, PU-2, and R-PG in the SRAM cell 100c. The active region 102P also extends continuously into the dummy cell region 202. The B-B line intersects another active region 102, specifically an n-type active region 102N that provides the channel and source/drain regions for transistors PG-1, PD-1, PD-2, and PG-2 in the same SRAM cell 100c. The active region 102N also extends into the dummy cell region 202. Each transistor's channel region includes vertically stacked nanostructures 110 that serve as channel layers. The channel region is sandwiched between two source/drain regions. Transistors PU-1 and PG-1 share the same gate structure 104b, while transistors PU-2 and PD-2 share the same gate structure 104c. The gate structures 104d and 104e, associated with transistors PG-2 and R-PG, respectively, are segments of the same gate line 104.

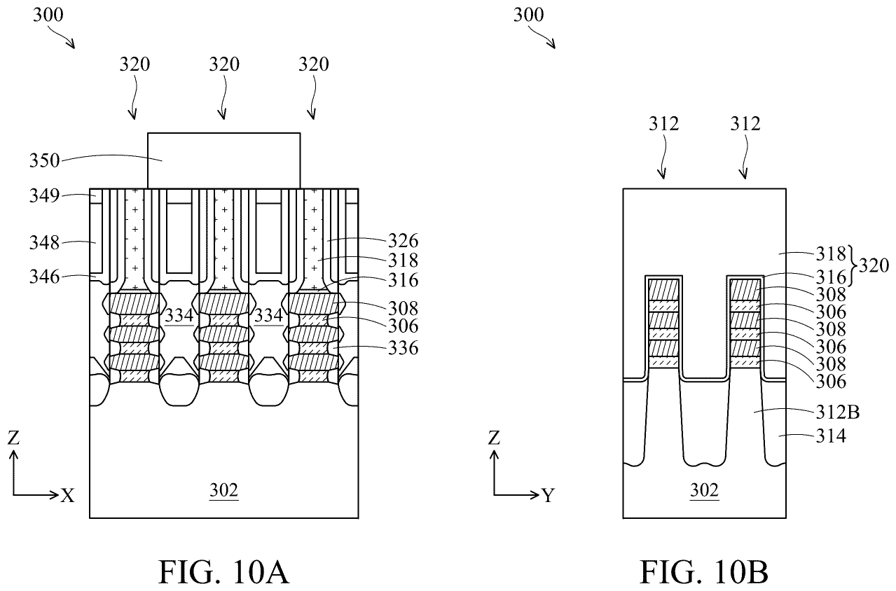

In FIG. 9A, the OD-cut feature 132 divides the active region 102P into two segments. The OD-cut feature 132 may be a multi-structure. In the illustrated embodiment, the OD-cut feature 132 includes a bottom portion 132a, an etch stop liner 132b, and a dielectric layer 132c. In some embodiments, the bottom portion 132a is a shallow trench isolation (STI) feature (e.g., STI feature 314 in FIG. 10B) disposed on a cut end of the active region 102P. The depicted top surface of the bottom portion 132a has a concave profile due to various etching losses through the manufacturing steps. The etch stop liner 132b may include silicon nitride or aluminum nitride. The dielectric layer 132c may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The etch stop liner 132b and the dielectric layer 132c are embedded in the bottom portion 132a due to the bottom portion 132a's concave profile.

Because the OD-cut feature 132 replaces a source/drain region, the transistor adjacent to PU-1 has only one source/drain region located on one side of the gate structure 104a and is therefore rendered non-functional. In FIG. 9B, the CPODE feature 134a replaces a portion of a gate line 104 and directly abuts the source/drain region of the transistor PG-1, which is a functional source/drain region. Unlike OD-cut features, CPODE features extend significantly deeper into the substrate and require a longer etch time to form. If a CPODE feature were formed as a long, continuous structure, the extended etch process could damage the abutting source/drain region of the PG-1 transistor, increasing the failure bit count of edge cells. To mitigate this risk, the length of the CPODE feature 134a is carefully controlled to preserve the integrity of nearby functional source/drain regions, as discussed above. Also shown in FIG. 9B is another CPODE feature 134d. Since this feature is located farther from the edge bit cells and does not interface with any functional source/drain region, it poses less impact on SRAM cell performance. Accordingly, the length of the CPODE feature 134d may be more flexible and can be equal to or even greater than that of the CPODE feature 134a.

Reference is now made to FIGS. 10A to 14B, which illustrate an exemplary CPODE process in forming CPODE features, such as the CPODE features 134 in FIGS. 5-8. The CPODE method described herein is merely an example and is not intended to limit the present disclosure to what is explicitly described associated with FIGS. 10A to 14B. Additional steps can be provided before, during and after the described steps, and some steps described can be replaced, eliminated, or moved around for additional embodiments of the method. Not all steps are described herein in detail for reasons of simplicity. In FIGS. 10A to 14B, the figures numbered with appendix “A” represent cross-sectional views taken in the X-Z plane, and the figures numbered with appendix “B” represent cross-sectional views taken in the Y-Z plane.

As shown in FIGS. 10A and 10B, a semiconductor device 300 includes a substrate 302 and fin-shaped structures 312 protruding from the substrate 302. In some embodiments, the semiconductor device 300 may represent the semiconductor device 10 in FIG. 1. In some embodiments, the substrate 302 may be a semiconductor substrate such as a silicon (Si) substrate. Alternatively, the substrate 302 may include a compound semiconductor and/or an alloy semiconductor. Further, the substrate 302 may optionally include an epitaxial layer (epi-layer), may be strained for performance enhancement, may include a silicon-on-insulator (SOI) or a germanium-on-insulator (GeOI) structure, and/or may have other suitable enhancement features.

The fin-shaped structures 312 each include a fin-shaped base 312B and an active region disposed on the fin-shaped base 312B. The active region rises above the isolation feature 314, which is disposed on sidewalls of the fin-shaped base 312B. In some embodiments, the active region of the fin-shaped structures 312 may represent the active regions 102 in FIGS. 5 and 6. Particularly, the two adjacent fin-shaped structures 312 in FIG. 8B may provide the p-type active region 102P and the n-type active region 102N, respectively. Dummy gate stacks 320 extend across the fin-shaped structure 312, defining channel regions underneath and source/drain regions sandwiching the channel regions. In channel regions, the active region includes channel layers 308 interleaved by sacrificial layers 306. In source/drain regions, the active region include epitaxial source/drain features 344. Inner spacers 336 separate the epitaxial source/drain features 344 from direct contacting the sacrificial layers 306.

In some embodiments, the sacrificial layers 306 include silicon germanium (SiGe) and the channel layers 308 include silicon (Si). It is noted that three (3) layers of the sacrificial layers 306 and three (3) layers of the channel layers 308 are alternately arranged as illustrated in FIG. 8A, which is for illustrative purposes only and not intended to be limiting beyond what is specifically recited in the claims. It can be appreciated that any number of epitaxial layers may be formed. The number of layers depends on the performance needs for the semiconductor device 300. In some embodiments, the number of channel layers 308 is between 2 and 10.

The isolation feature 314 may be a shallow trench isolation (STI) feature. In some embodiments, the isolation feature 314 is a dielectric layer that may include silicon oxide, silicon oxynitride, fluorine-doped silicate glass (FSG), a low-k dielectric, combinations thereof, and/or other suitable materials.

The inner spacers 336 may include silicon carbonitride (SiCN), silicon oxycarbonitride (SiOCN), silicon nitride (SiN), silicon oxycarbide (SiOC), or silicon oxynitride (SiON). The formation of the inner spacers 336 may include recessing the fin-shaped structure 312 in the source/drain regions to form source/drain recesses prior to the epitaxial growing of the epitaxial source/drain features 344, laterally recessing the sacrificial layers 306 from the source/drain recesses to form inner spacer cavities, and filling the inner spacer cavities with dielectric material(s) as the inner spacers 336. After the inner spacers 336 are formed, the epitaxial source/drain features 344 may be epitaxially grown from the source/drain recesses.

The epitaxial source/drain features 344 may be n-type or p-type. When the epitaxial source/drain feature 344 is n-type, the epitaxial source/drain feature 344 may include silicon (Si) and an n-type dopant, such as phosphorus (P), arsenic (As), antimony (Sb), or a combination thereof. When the epitaxial source/drain feature 344 is p-type, the epitaxial source/drain feature 344 may include silicon germanium (SiGe) and a p-type dopant, such as boron (B), boron difluoride (BF₂), or a combination thereof. As shown in FIG. 10A, in some embodiments, the epitaxial source/drain feature 344 may include multiple layers. For example, the epitaxial source/drain feature 344 may include a buffer epitaxial layer that is dopant free, a lightly doped epitaxial feature over the buffer epitaxial layer, and a heavily doped epitaxial feature over the lightly doped epitaxial feature. The lightly doped epitaxial feature includes smaller dopant concentration and impurity concentration to reduce crystalline defects. The heavily doped epitaxial feature accounts for a majority of the volume to reduce contact resistance.

The dummy gate stacks 320 serve as a placeholder to undergo various processes and are to be removed and replaced by functional gate structures. The dummy gate stacks 320 includes a dummy dielectric layer 316 and a dummy electrode layer 318. The dummy dielectric layer 316 may be conformally deposited on the fin-shaped structures 312. The term “conformally” may be used herein for ease of description of a layer having substantially uniform thickness over various regions. In some embodiments, the dummy dielectric layer 316 may include silicon oxide, and the dummy electrode layer 318 may include polysilicon. Sidewalls of the dummy gate stacks 320 are covered with the gate spacers 326. The gate spacers 326 may be a single layer or a multi-layer. The at least one layer in the gate spacers 326 may include silicon carbonitride, silicon oxycarbide, silicon oxycarbonitride, or silicon nitride.

Between opposing sidewalls of the gate spacers 326, the epitaxial source/drain feature 344 is covered under the contact etch stop layer (CESL) 346 and the interlayer dielectric (ILD) layer 348. A capping layer 349 is deposited on the ILD layer 348. In some embodiments, the CESL 246 may include silicon nitride or aluminum nitride, the ILD layer 248 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the capping layer 249 may include silicon nitride, silicon carbonitride, silicon carbide, or silicon oxycarbonitride. A planarization (e.g., a CMP process) may be performed to remove excess capping layer 349 and to expose the dummy gate stack 320. After the planarization, top surfaces of the capping layer 349, the CESL 346, the gate spacers 326, and the dummy gate stacks 320 are coplanar.

Also shown in FIG. 10A, a patterned mask layer 350 is formed over the semiconductor device 300 to expose selected portions of the dummy gate stacks 320. In subsequent processes, the exposed portions of the dummy gate stacks 320 will be removed.

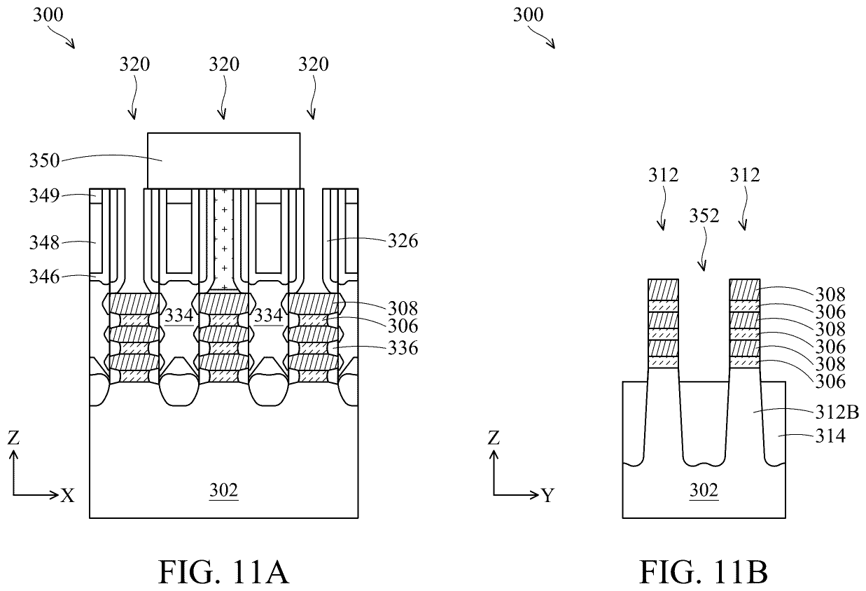

Referring to FIGS. 11A and 11B, the exposed portions of the dummy gate stacks 320 are removed to form trenches 352. The removal of the exposed portions of the dummy gate stacks 320 may include one or more etching processes that are selective to the materials of the dummy gate stacks 320. For example, the removal of the dummy gate stack 320 may be performed using as a selective wet etch, a selective dry etch, or a combination thereof that is selective to the dummy gate stack 320. The etching selectivity between the dummy gate stack 220, the gate spacers 226, and the capping layer 249 allows the opening defined in the patterned mask layer 350 to not necessarily be strictly aligned with the sidewalls of the gate spacers 326, thereby enlarging process windows. After the performing of the etching process, portions of the fin-shaped structures 312 in the channel regions that were previously covered by the dummy gate stacks 320 are exposed.

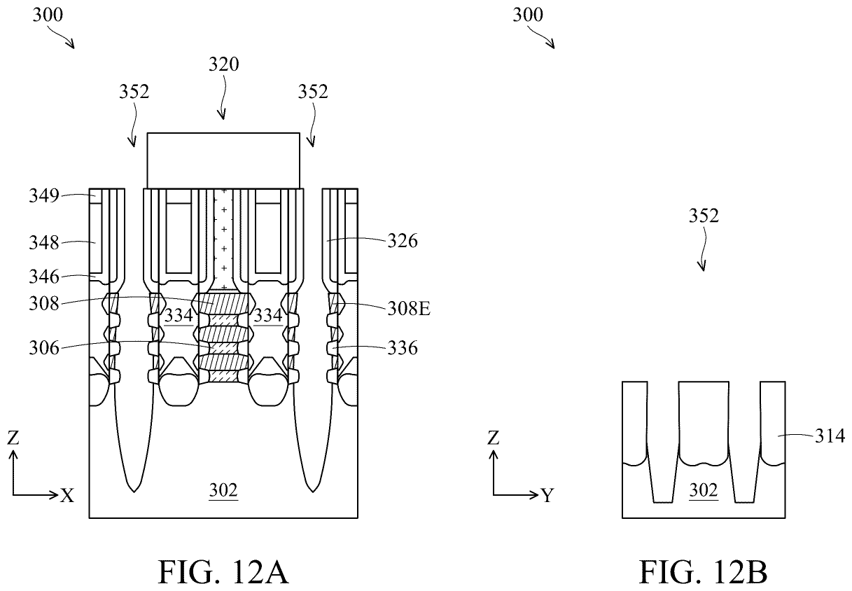

Referring to FIGS. 12A and 12B, the exposed portions of the fin-shaped structures 312 are further removed from the trenches 352. As a result, the trench 352 further extends downward. An etching process may be performed to selectively remove the exposed portions of the fin-shaped structures 312. For example, the removal of the fin-shaped structures 312 may be performed using as a selective wet etch, a selective dry etch, or a combination thereof that is selective to the fin-shaped structure 312. In the present embodiment, the duration of the etching process is controlled such that the trenches 352 extend through the isolation feature 314 and extends into the substrate 302. As shown in FIG. 12B, the isolation feature 314 remains substantially intact due to etching selectivity. As shown in FIG. 12A, the gate spacers 326 may protect a portion of the fin-shaped structure 312 directly under the gate spacers 326 from removing. Exposed on sidewalls of the trenches 352 are the remaining end portions of the channel layers 308 (denoted as 308E) and the inner spacers 336.

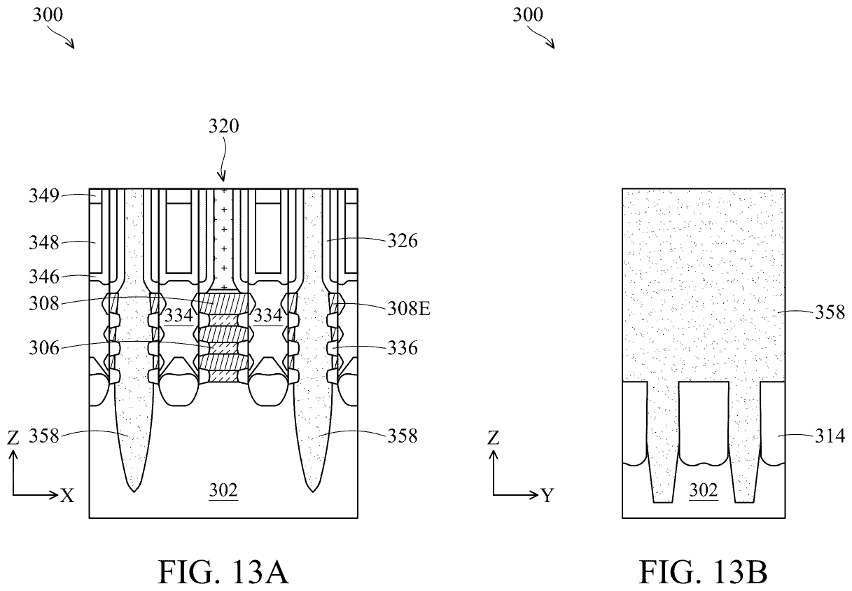

Referring to FIGS. 13A and 13B, the CPODE features 358 are formed by depositing dielectric material(s) in the trenches 352. In some embodiments, the CPODE features 358 may be the CPODE features 134 in FIGS. 5 and 6. The CPODE features 358 may be a single layer or a bi-layer structure. In some embodiments, the CPODE features 358 is a bi-layer structure with a liner layer of a nitride (e.g., silicon nitride or silicon carbonitride) and a bulk layer of an oxide (e.g., silicon oxide). A planarization (e.g., a CMP process) may be performed to remove excess portions of the dielectric materials of the CPODE features 358 and the patterned mask layer 350 to expose other dummy gate stacks 320.

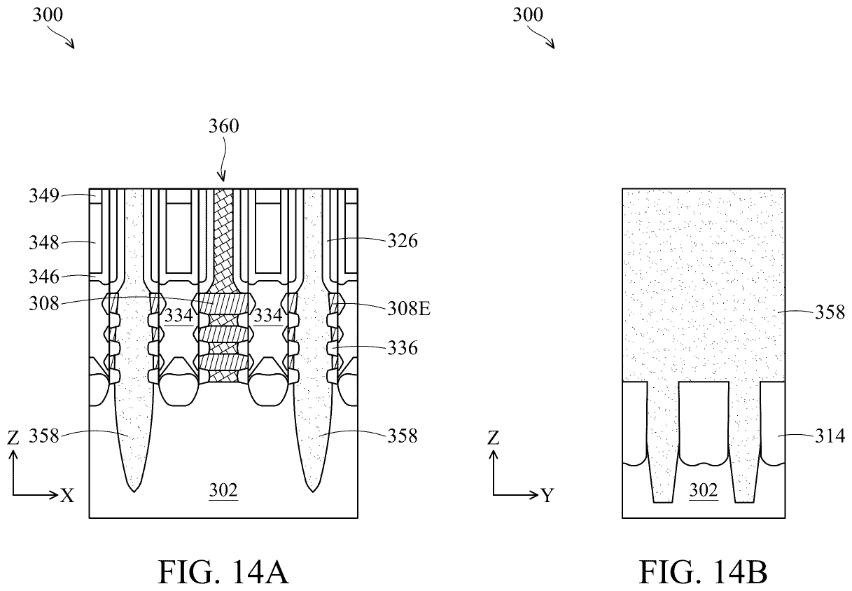

Referring to FIGS. 14A and 14B, the dummy gate stacks 320 are replaced by the metal gate structures 360. The formation of the metal gate structures 360 may include removing the dummy gate stacks 320 to form a gate trench, removing the sacrificial layers 306 from the gate trench to release the channel layers 308, and depositing the metal gate structures 360 in the gate trench to wrap around each of the channel layers 308. The metal gate structures 360 may include a gate dielectric layer and a gate electrode layer over the gate dielectric layer. Not explicitly shown, the gate dielectric layer may further includes an interfacial layer interfacing the channel layer 308 and a high-k dielectric layer over the interfacial layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-k dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The high-k dielectric layer may be formed by ALD, physical vapor deposition (PVD), CVD, oxidation, and/or other suitable methods.

The gate electrode layer of the gate structures 360 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 250c may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. In some embodiments, the gate structures 360 may include a p-type gate structure portion and an n-type gate structure portion. The p-type gate structure portion includes p-type work function metal layers disposed closer to the channel layers 308. The n-type gate structure portion includes n-type work function metal layers disposed closer to the channel layer 308.

Although not intended to be limiting, embodiments of the present disclosure provide one or more of the following advantages. For example, embodiments of the present disclosure provide a continuous dielectric “wall” for separating the functional bit cells in a memory array from surrounding dummy cells. The continuous dielectric “wall” includes first type isolation structures and second type isolation structures. In some embodiments, the first type isolation structures are OD-cut features, and the second type isolation structures are CPODE features. Since the CPODE features extends downward more than the OD-cut features, the formation of a continuously long CPODE feature poses risk to the functions of edge bit cells. Therefore, embodiments of the present disclosure divide the CPODE features into shorter segments interleaved with segments of the gate lines. Such a configuration improves the integrity of the memory array and reduces failure bit count in the edge bit cells. The embodiments of the present disclosure in forming the isolation structures can be readily integrated into existing semiconductor manufacturing processes.

In one exemplary aspect, the present disclosure is directed to a semiconductor structure. The semiconductor structure includes a plurality of active regions distributed along a first direction and each extending lengthwise along a second direction perpendicular to the first direction, a plurality of gate lines distributed along the second direction and each extending lengthwise along the first direction, a first active region break intersecting a first one of the active regions, a second active region break intersecting a second one of the active regions, and an isolation structure abutting the first and second active region breaks and extending lengthwise along the first direction. The isolation structure is disposed between the first and second ones of the active regions along the first direction. In some embodiments, the isolation structure intersects at least one of the active regions disposed between the first and second ones of the active regions. In some embodiments, the isolation structure intersects two or more of the active regions disposed between the first and second ones of the active regions. In some embodiments, the isolation structure aligns with first and second segments of one of the gate lines. In some embodiments, the first segment of the one of the gate lines abuts the first active region break, and the second segment of the one of the gate lines abuts the second active region break. In some embodiments, the active regions are distributed along the first direction with a pitch, and a length of the isolation structure along the first direction ranges from about 1.5 times the pitch to about 2.5 times the pitch. In some embodiments, the length of the isolation structure is 2 times the pitch. In some embodiments, the isolation structure is a first isolation structure, the semiconductor structure further includes a second isolation structure aligned with the first isolation structure and abutting the first active region breaks. A length of the second isolation structure along the first direction is larger than a length of the first isolation structure. In some embodiments, the first and second active region breaks are disposed over an edge between a first cell region and a second cell region, and the isolation structure is disposed within the second cell region. In some embodiments, the isolation structure extends downwardly deeper than the first and second active region breaks.

In another exemplary aspect, the present disclosure is directed to a semiconductor device. The semiconductor device includes a first cell region comprising a plurality of active regions distributed evenly along a first direction with a first pitch and a plurality of gate lines distributed evenly along a second direction with a second pitch, the first direction perpendicular to the second direction, the first cell region comprising a first edge and a second edge intersecting the first edge at a corner of the first cell region, a second cell region adjacent to the first cell region, and an isolation structure disposed in the second cell region and spaced apart from the first edge of the first cell region with a distance smaller than the second pitch. The isolation structure extends lengthwise along the first direction with a length ranging from about 1.5 times the first pitch to about 2.5 times the first pitch. In some embodiments, the length of the isolation structure is 2 times the first pitch. In some embodiments, the isolation structure is spaced apart from an edge one of the plurality of gate lines for a distance equal to the second pitch. In some embodiments, the isolation structure is a first isolation structure, and the semiconductor device further includes a second isolation structure disposed in the second cell region and aligned with the first isolation structure. A length of the second isolation structure is larger than the length of the first isolation structure. In some embodiments, the semiconductor device further includes an active region cut feature disposed on the first edge of the first cell region and abutting both the first and second isolation structures. In some embodiments, the isolation structure is a first isolation structure, and the semiconductor device further includes a second isolation structure disposed in the second cell region and aligned with one of the plurality of gate lines in the first cell region. A shortest distance between an end point of the second isolation structure and the second edge of the first cell region along the first direction is at least one times the first pitch. In some embodiments, the isolation structure abuts a source/drain region of a transistor in an edge cell of the first cell region.

In yet another exemplary aspect, the present disclosure is directed to a method of forming a semiconductor device. The method includes forming a first active region and a second active region, forming a first isolation structure intersecting the first active region, forming a first gate structure across the first and second active regions, forming a second gate structure across the first and second active regions, the first isolation structure disposed between and interfacing with the first and second gate structures, and replacing a portion of the second gate structure with a second isolation structure. The second isolation structure is aligned with the second gate structure and interfacing with the second active region and the first isolation structure. In some embodiments, the second isolation structure is deeper than the first isolation structure. In some embodiments, a transistor is formed at an intersection of the first gate structure and the second active region, and wherein the second isolation structure abuts a source/drain region of the transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of active regions distributed along a first direction and each extending lengthwise along a second direction perpendicular to the first direction;
a plurality of gate lines distributed along the second direction and each extending lengthwise along the first direction;
a first active region break intersecting a first one of the active regions;
a second active region break intersecting a second one of the active regions; and
an isolation structure abutting the first and second active region breaks and extending lengthwise along the first direction,
wherein the isolation structure is disposed between the first and second ones of the active regions along the first direction.

2. The semiconductor structure of claim 1, wherein the isolation structure intersects at least one of the active regions disposed between the first and second ones of the active regions.

3. The semiconductor structure of claim 1, wherein the isolation structure intersects two or more of the active regions disposed between the first and second ones of the active regions.

4. The semiconductor structure of claim 1, wherein the isolation structure aligns with first and second segments of one of the gate lines.

5. The semiconductor structure of claim 4, wherein the first segment of the one of the gate lines abuts the first active region break, and the second segment of the one of the gate lines abuts the second active region break.

6. The semiconductor structure of claim 1, wherein the active regions are distributed along the first direction with a pitch, and wherein a length of the isolation structure along the first direction ranges from about 1.5 times the pitch to about 2.5 times the pitch.

7. The semiconductor structure of claim 6, wherein the length of the isolation structure is 2 times the pitch.

8. The semiconductor structure of claim 1, wherein the isolation structure is a first isolation structure, the semiconductor structure further comprising:
a second isolation structure aligned with the first isolation structure and abutting the first active region breaks,
wherein a length of the second isolation structure along the first direction is larger than a length of the first isolation structure.

9. The semiconductor structure of claim 1, wherein the first and second active region breaks are disposed over an edge between a first cell region and a second cell region, and wherein the isolation structure is disposed within the second cell region.

10. The semiconductor structure of claim 1, wherein the isolation structure extends downwardly deeper than the first and second active region breaks.

11. A semiconductor device, comprising:
a first cell region comprising a plurality of active regions distributed evenly along a first direction with a first pitch and a plurality of gate lines distributed evenly along a second direction with a second pitch, the first direction perpendicular to the second direction, the first cell region comprising a first edge and a second edge intersecting the first edge at a corner of the first cell region;
a second cell region adjacent to the first cell region; and
an isolation structure disposed in the second cell region and spaced apart from the first edge of the first cell region with a distance smaller than the second pitch,
wherein the isolation structure extends lengthwise along the first direction with a length ranging from about 1.5 times the first pitch to about 2.5 times the first pitch.

12. The semiconductor device of claim 11, wherein the length of the isolation structure is 2 times the first pitch.

13. The semiconductor device of claim 11, wherein the isolation structure is spaced apart from an edge one of the plurality of gate lines for a distance equal to the second pitch.

14. The semiconductor device of claim 11, wherein the isolation structure is a first isolation structure, the semiconductor device further comprising:
a second isolation structure disposed in the second cell region and aligned with the first isolation structure,
wherein a length of the second isolation structure is larger than the length of the first isolation structure.

15. The semiconductor device of claim 14, further comprising:
an active region cut feature disposed on the first edge of the first cell region and abutting both the first and second isolation structures.

16. The semiconductor device of claim 11, wherein the isolation structure is a first isolation structure, the semiconductor device further comprising:
a second isolation structure disposed in the second cell region and aligned with one of the plurality of gate lines in the first cell region, wherein a shortest distance between an end point of the second isolation structure and the second edge of the first cell region along the first direction is at least one times the first pitch.

17. The semiconductor device of claim 11, wherein the isolation structure abuts a source/drain region of a transistor in an edge cell of the first cell region.

18. A method of forming a semiconductor device, comprising:
forming a first active region and a second active region;
forming a first isolation structure intersecting the first active region;
forming a first gate structure across the first and second active regions;
forming a second gate structure across the first and second active regions, wherein the first isolation structure is disposed between and interfacing with the first and second gate structures; and
replacing a portion of the second gate structure with a second isolation structure, wherein the second isolation structure is aligned with the second gate structure and interfacing with the second active region and the first isolation structure.

19. The method of claim 18, wherein the second isolation structure is deeper than the first isolation structure.

20. The method of claim 18, wherein a transistor is formed at an intersection of the first gate structure and the second active region, and wherein the second isolation structure abuts a source/drain region of the transistor.
